(19) United States
(12) Patent Application Publication
(10) Pub. No.: US 2005/0276424 A1
(43) Pub. Date: Dec. 15, 2005

(54) Computer speaker beep routing

(76) Inventors: Charles N. Shaver, Cypress, TX (US); Larry W. Kunkel, Spring, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/854,227

(22) Filed: May 27, 2004

(51) Int. Cl. H03G 3/00; H04R 3/00

(52) U.S. Cl. 381/104; 381/111; 381/333

(57) ABSTRACT

A computer comprising an internal chassis speaker; an external chassis speaker; and a routing circuit that routes a speaker beep signal generated by the computer to the external chassis speaker and to the internal chassis speaker through a volume control circuit responsive to an external control signal.

### BACKGROUND

The Basic Input/Output System (BIOS) is the lowest-level software in a computer, providing an interface between the hardware and the operating system. The BIOS provides access to system hardware and enables the creation of higher-level operating systems that execute software applications. One particularly important operation performed by the BIOS is booting up the computer when power is applied and when the computer is reset.

The first operation performed by the BIOS when it boots the computer is a Power-On Self-Test (POST). The POST is a built-in diagnostic program that verifies that all requisite hardware components are present and functioning properly. The BIOS communicates problems identified during POST by generating error messages. Because POST is performed prior to the video processor being activated, the error messages are typically encoded in sounds (beep patterns) provided to an internal chassis speaker. The beep patterns, which depend in the manufacturer of the BIOS, can be used to diagnose hardware problems with the computer. In addition, during run-time operations, diagnostic operations may also generate beep patterns identifying current conditions. These and other pulse width modulated beep signals are commonly referred to as speaker beep signals.

Traditionally, speaker beep signals are routed to an internal chassis speaker and are not controllable by the operator. This has not changed with the advent of external chassis speakers; in modern computers speaker beep signals are routed to the internal speaker while audio signals are routed to the external speakers.

### SUMMARY

In one embodiment, a computer is disclosed. The computer comprises an internal chassis speaker; an external chassis speaker; and a routing circuit that routes a speaker beep signal generated by the computer to the external chassis speaker and to the internal chassis speaker through a volume control circuit responsive to an external control signal.

In another embodiment, a circuit for routing a speaker beep signal in a computer having a processor chipset and internal and external chassis speakers is disclosed. The circuit comprises first routing means for routing to the external chassis a speaker beep signal received from the processor chipset; first volume control means for controlling a volume of the speaker beep signal routed to the external chassis speaker; second routing means for routing to the internal chassis speaker the received speaker beep signal; and second volume control means for adjusting a volume of the speaker beep signal routed to the internal chassis speaker in response to an external control signal.

In a further embodiment, a method for routing a speaker beep signal in a computer is disclosed. The method comprises: routing the speaker beep signal to an external chassis speaker; and adjusting a magnitude of the speaker beep signal routed to the external chassis speaker in response to a control input signal.

### BRIEF DESCRIPTION OF THE DRAWINGS

FIG. 1 is a block diagram of one exemplary computer system in which aspects of the present invention can be implemented.

FIG. 2 is a functional block diagram of the routing of a speaker beep signal in accordance with one embodiment of the present invention.

FIG. 3 is a simplified circuit diagram of the routing of a speaker beep signal in accordance with one embodiment of the present invention.

FIG. 4 is an interface block of an audio codec shown in FIG. 2 in accordance with one embodiment of the present invention.

FIG. 5A is a flow chart of the operations performed to route a speaker beep signal in a computer in accordance with one embodiment of the present invention.

FIG. 5B is a flow chart of the operations performed to route a speaker beep signal in a computer in accordance with one embodiment of the present invention.

### DETAILED DESCRIPTION

Speaker routing circuitry that routes a speaker beep signal to an external chassis speaker of a computer. In one embodiment, the speaker beep signal destined for the external speaker is routed through an audio codec to be mixed with an audio signal generated elsewhere in the computer, and which provides operator control of the volume of the external speaker beep signal. In one embodiment, the speaker routing circuitry also routes the speaker beep signal to an internal chassis speaker. In one embodiment, the speaker routing circuitry also comprises a volume control circuit that permits operator control of the speaker beep signal destined for the internal chassis speaker.

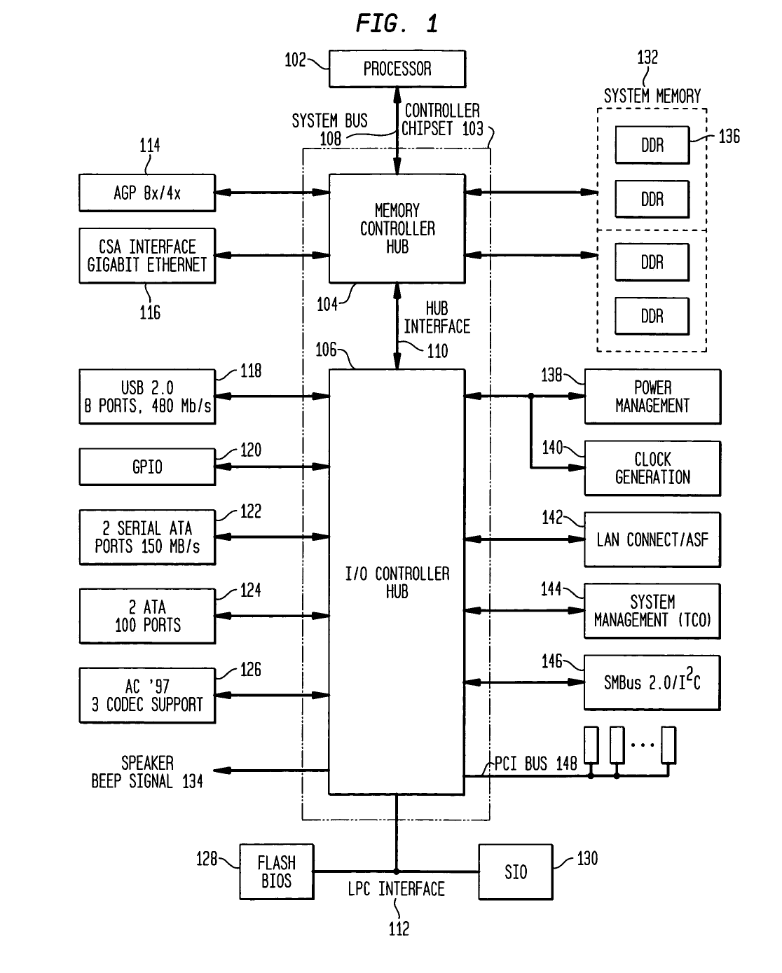

FIG. 1 is a block diagram of an exemplary computer system 100 suitable for implementing embodiments of the present invention. In one exemplary application, computer system 100 can be, for example, a desktop computer, point-of-sale computer or any other computer. It should be appreciated by those of ordinary skill in the art that the present invention can be implemented in any type of computer having any computer architecture now or later developed.

The exemplary computer system 100 comprises a processor 102 connected directly to a controller chipset 103 that manages the flow of data in computer 100. Chipset 103 comprises a memory controller hub 104 connected to processor 102 via a front side bus (FSB) 108. Memory controller hub 104 is connected to a second hub, referred to as an input/output (I/O) controller hub 106 via a hub interface bus 110. In one embodiment, processor 102 is a microprocessor such a Pentium IV or other suitable microprocessor, and controller chipset 103 is, for example, an 875P chipset, commercially available from Intel, Inc. Collectively, processor 102 and controller chipset 103 are often referred to as a processor chipset. Such a processor chipset may include a single or multiple integrated circuits depending on the implemented architecture.

Memory controller hub 104 manages the flow of information between various interfaces, commonly referred to as host bridge interfaces. Memory controller hub 104 manages the FSB interface 108 with processor 102, and the hub interface 110 with I/O controller 106. Memory controller hub 104 also supports an external AGP graphics device (not shown) via an AGP interface 114. Memory controller hub 104 also provides a Communications Streaming Architecture (CSA) Interface 116 that connects memory controller hub 104 to a Gigabit Ethernet (GbE) controller (not shown). Memory controller hub 104 also supports system memory 132, which, in the embodiment shown in FIG. 1, comprises Double Data Rate (DDR) memory components 136. Memory controller hub 104 arbitrates between these interfaces, providing data coherency and performing address translation as necessary.

I/O controller hub 106 controls the remainder of computer 100, integrating controllers (not shown) to support two ATA 100 ports 124, two Serial ATA ports 122, eight external Universal Serial Bus (USB) 2.0 ports 118, an LPC interface 112, flash BIOS 128, SIO 130, general purpose input/output (GPIO) 120, audio CODer/DECoder (codec) 126, power management 138, clock generation 140, LAN connection 142, system management 144 and PCI BUS 148. I/O Controller Hub 106 provides the data buffering and interface arbitration required to ensure these system interfaces operate efficiently and have the bandwidth necessary to enable the system to operate efficiently.

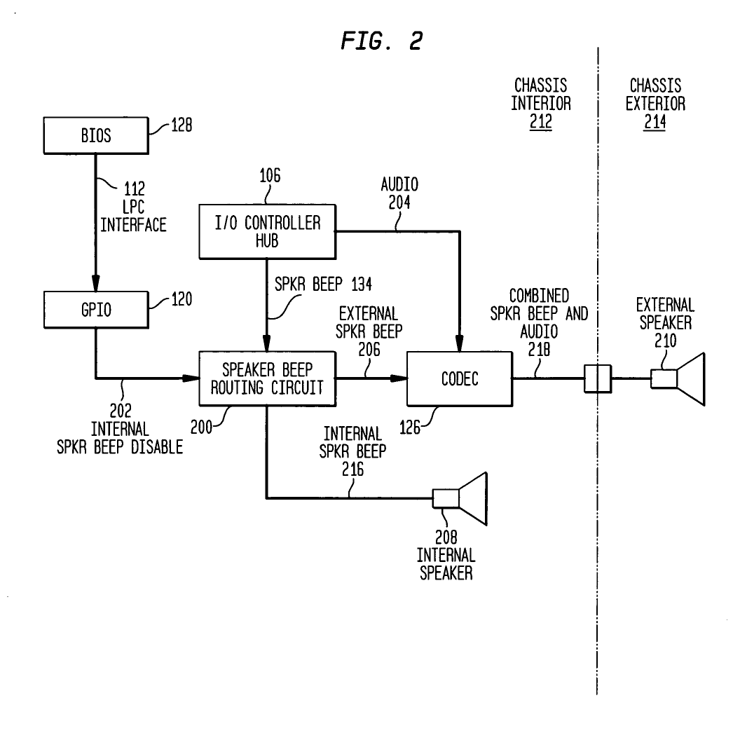

FIG. 2 is an architectural block diagram of selected elements of computer system 100 related to the routing of speaker beep signals in accordance with one embodiment of the present invention. In the exemplary embodiment shown in FIG. 2, computer system 100 comprises one internal chassis speaker 208 located in the interior 212 of the computer chassis, and one external chassis speaker 210 located in the exterior 214 of the computer chassis. It should be appreciated by those of ordinary skill in the art that this illustrative configuration is exemplary only and that the present invention can be implemented in a computer system having more than one internal and/or more than one external chassis speaker.

I/O controller hub 106, as noted, is operationally coupled to audio codec 126. As shown in FIG. 2, I/O controller hub 106 generates audio signals 204 that are routed to audio codec 126 to be processed for output to external speaker 210. Referring again to FIG. 1, I/O controller hub 106 also generates speaker beep signals 134. As noted, speaker beep signals 134 are invoked by BIOS 128 as well as other software applications executing on processor 102. Once invoked, processor 102 writes to registers in I/O controller hub 106 causing the generation of a speaker beep signal 134.

Computer 100 also comprises speaker beep routing circuitry 200 configured to route speaker beep signal 134 to external chassis speaker 210. As shown in FIG. 2, routing circuit 200 receives speaker beep signal 134 from I/O controller hub 106, and routes the speaker beep signal to audio codec 126. The speaker beep signal provided to audio codec 126 is referred to as external beep signal 206. Similarly, speaker beep routing circuit 200 may route speaker beep signal 134 to internal chassis speaker 208. The speaker beep signal provided to internal speaker 208 is referred to as internal speaker beep signal 216. It should be appreciated that to route speaker beep signal 134 to external chassis speaker 210 (as external speaker beep signal 206) and, in certain embodiments, to internal chassis speaker 208 (as internal speaker beep signal 216) embodiments of routing circuitry 200 may gate channel, process or use speaker beep signal 134 to generate a separate signal 206 and, perhaps, signal 216. It should be appreciated that external speaker signal 206 and internal speaker signal 216 may be routed using the same different technique.

In one embodiment, routing circuitry 200 comprises a volume control circuit that permits control of the speaker beep signal destined for internal speaker 208. In the implementation shown in FIG. 2, routing circuit 200 receives an internal speaker beep disable signal 206 that controls whether internal speaker beep signal 216 is provided to internal speaker 208. BIOS 128 determines the state of speaker beep disable signal 206 through the setting of a bit in general purpose input/output (GPIO) 120. As one of ordinary skill in the art would appreciate, internal speaker beep disable signal 206 can be generated through other mechanisms now or later developed. It should also be appreciated that in alternative embodiments, the volume of internal speaker beep signal is controlled in addition to or instead of the muting of internal speaker beep signal 134.

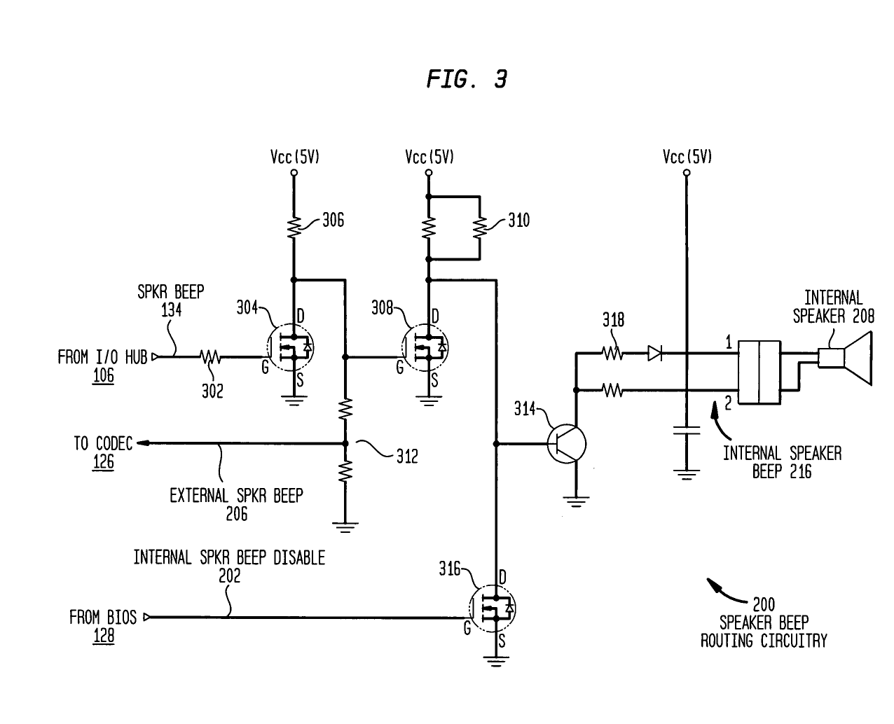

FIG. 3 is a simplified schematic diagram of one embodiment of speaker beep routing circuit 200. Speaker beep signal 134 is received from I/O controller hub 106, as noted above. The signal line on which speaker beep signal 202 travels is connected to the gate of a field effect transistor (FET) 304. As shown in FIG. 3, speaker beep signal 134 is routed through a resistor 302 to adjust the voltage level as appropriate for FET 304. FET 304 has a drain connected to a 5 volt DC source through a pull-up resistor 306. The source of FET 304 is connected to ground.

Speaker beep signal 134 generally is a square wave that alternates between 3.3 volts and ground. As it alternates between these two values, speaker beep signal 134 turns FET 304 on and off. This causes the output or drain of FET 304 to correspondingly alternate between 5.0 volts and ground. Effectively, then, FET 304 shifts the voltage level of speaker beep signal 134.

The output of FET 304 is provided to a voltage divider circuit 312. Voltage divider circuit 312 comprises a series arrangement of two resistors connected between the drain of FET 304 and ground, with the output of the circuit provided at the junction of the two resistors. The output of voltage divider circuit 312, external speaker beep signal 206, is provided to audio codec 126, as noted above. It should be understood that voltage divider circuit 312 adjusts the level of speaker beep signal 134 to a level appropriate for codec 126. Audio codec 126 is described in detail below with reference to one exemplary embodiment.

Speaker beep routing circuitry 200 also comprises a second FET 308 that controls the application of a 5 Volt DC source to a transistor 314 also included in the routing circuitry. The gate of FET 308 is connected directly to the drain of FET 304. The source of FET 308 is connected to ground while the drain of FET 308 is connected to a 5 Volt DC source through a pull-up resistor network 310. Resistor network 310 comprises, in this embodiment, a parallel arrangement of two pull-up resistors due to the current draw for internal chassis speaker 208. The drain or output of FET 308 is connected to the base of transistor 314. The collector of transistor 314 is connected to internal speaker 208 while the emitter of the transistor is connected to ground.

When FET 308 is turned off, current flows into the base of transistor 314, driving the transistor into saturation. Current then flows from the base to the collector of transistor 314, driving internal speaker 208. When FET 308 is turned on, the 5 Volt DC source is connected to ground through the FET, and no current is applied to transistor 314.

As noted, certain embodiments of speaker beep routing circuitry 200 also enable the volume of internal speaker beep signal 216 to be adjusted. In this embodiment, a speaker beep disable signal 206 is received by routing circuitry 200 from BIOS 128. In one implementation, disable signal 206 reflects the state of an associated bit in GPIO 120 which is set by BIOS 128. A control setting for muting the internal speaker beep signal 216 is included in the BIOS settings which are stored in persistent memory, and which can be changed by the operator, for example, during the boot-up process. During the boot process BIOS 128 reads the BIOS setting and writes to the appropriate GPIO register, which is ultimately connected to the gate of FET 316. The drain of FET 316 is connected to the output of FET 308 while the source of FET 316 is connected to ground. As such, beep disable signal 206 serves to mute internal speaker 208. A high beep disable signal 208 will turn on FET 316, connecting the drain of FET 308 to ground and turning off transistor 314. A low beep disable signal 208 will permit FET 308 to turn transistor 314 on.

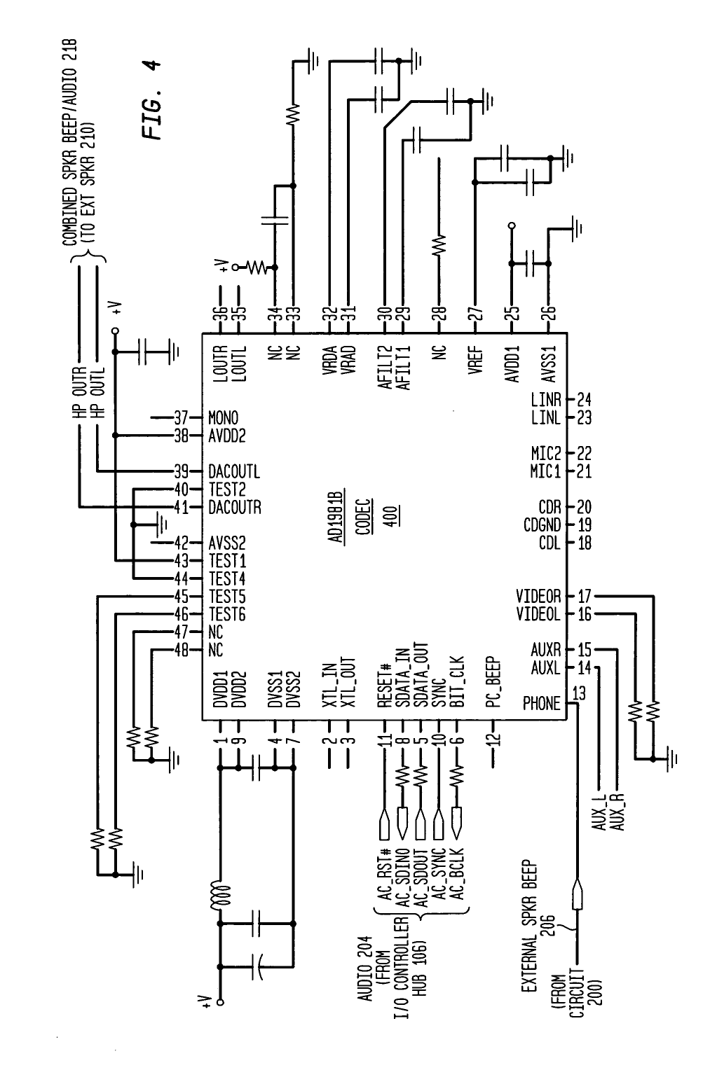

FIG. 4 is an interface block diagram of an exemplary embodiment of audio codec 126, referred to herein as audio codec 400. In this exemplary embodiment, audio codec 400 is an AD1981B Codec commercially available from Analog Devices, Inc. In this embodiment, audio signal 204 generated by I/O controller hub 106 comprises a series of signals provided to audio input pins 2, 3, 11, 8, 5, 10 and 6 of codec 400. External speaker beep signal 206, which is provided by routing circuit 200, is routed to “phone” pin 13 of audio codec 400. An audio driver provided with audio codec 400 can be used to control the volume of external beep signal 206 through the implemented operating system. For example, the operating system (not shown) displays an audio control window in response to an operator request to adjust the volume. Typically such control windows comprise an manipulatable slide bar representing a series of volume settings, and a checkbox to mute the signal. The volume control component of the operating system communicates the operator's selections to the audio codec driver which then controls audio codec 126 accordingly.

Audio codec 400 mixes the audio and speaker beep signals and provides the combined signal 218 on left and right headphone output pins 39 and 41, as shown in FIG. 4. The headphone pins are converted to external chassis speaker 210. It should be appreciated by those of ordinary skill in the art that another audio codec now or later developed can be implemented in alternative embodiments.

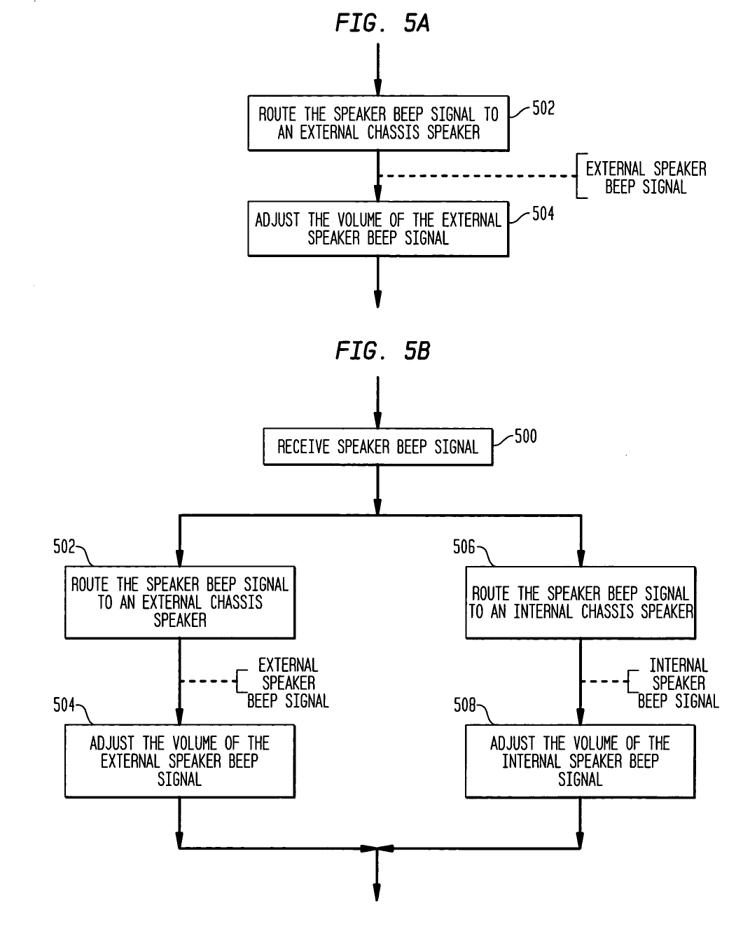

FIG. 5A is a flow chart of the operations performed by one embodiment of the present invention. Upon receipt of speaker beep signal 134, the signal is routed to external chassis speaker 210 at block 502. As noted, this may involve the gating, channeling, modification or other manipulation of the received speaker beep signal 134. In certain embodiments, it may comprise the generation of a new speaker beep signal based on the received speaker beep signal 134. In all of these and other embodiments, the signal routed to external speaker 210 is referred to as the external speaker beep signal.

At block 504 the volume of the external speaker beep signal is adjusted in response to external control commands. In one embodiment this may entail the enabling or disabling of the external speaker beep signal while in alternative embodiments it may entail adjusting the volume to one of a plurality of settings. In one embodiment, the external control command is controlled by the operator through the BIOS settings. Alternatively, the external control command is set programmatically or by the operator during real-time operations.

FIG. 5B is a flow chart of the operations performed by another embodiment of the present invention. Speaker beep signal 134 is shown as being received at block 500. The received speaker beep signal 134 is then concurrently routed to external speaker 210 and internal speaker 208. On the left-hand side of the flow chart, there are two blocks 502 and 504 which are the same as those addressed above. As noted, at blocks 502 and 504 the speaker beep signal is provided the exterior chassis speaker 210 and adjusted in response to an external command provided, for example, by the operator.

Similarly, at block 506, speaker beep signal 134 is routed to internal chassis speaker 208 of the computer. As noted, this may entail the gating, channeling, modification or other manipulation of the received speaker beep signal 134. In certain embodiments, it may comprise the generation of a new speaker beep signal based on the received speaker beep signal 134. In all of these and other embodiments, the signal routed to internal speaker 208 is referred to as the internal speaker beep signal.

At block 508 the volume of the internal speaker beep signal is adjusted in response to external control commands. In one embodiment this may entail the enabling or disabling of the internal speaker beep signal while in alternative embodiments it may entail adjusting the volume to one of a plurality of settings. Alternatively, the external control command is set programmatically or by the operator during real-time operations.

While various embodiments of the present invention have been described above, it should be understood that they have been presented by way of example only, and not limitation. For example, in an alternative embodiment audio signal 204 is also routed to internal speaker 208 by routing circuitry 200. In such an embodiment, a summer and amplifier circuit is also included in computer 100 as part of routing circuitry 200 or operationally interposed between circuit 200 and internal chassis speaker 208. Such a circuit would mix internal speaker beep signal 216 and audio signal 204, and amplify the combined signal for internal speaker 208.

1. A computer comprising:
an internal chassis speaker;
an external chassis speaker; and
a routing circuit that routes a speaker beep signal generated by the computer to the external chassis speaker and to the internal chassis speaker through a volume control circuit responsive to an external control signal.

2. The computer of claim 1, further comprising:
an audio codec that mixes the speaker beep signal with an audio signal received from the processor chipset, and that provides the external chassis speaker with the resulting combined speaker beep and audio signal.

3. The computer of claim 2, wherein the audio codec is configured to adjust a volume of routed speaker beep signal in response to a second external control signal.

4. The computer of claim 2, wherein the audio codec is configured to adjust a volume of the audio signal in response to a first external control signal.

5. The computer of claim 1, wherein the volume control circuit mutes the speaker beep signal routed to the internal speaker in response to the second external control signal.

6. The computer of claim 1, wherein the external control signal is a BIOS setting.

7. The computer of claim 1, wherein the routing circuit comprises:
a transistor having a base connected to a voltage source, an emitter connected to ground, and a collector connected to the internal chassis speaker; and
a first field-effect transistor having a gate controlled by the received speaker beep signal, a source connected to ground, and a drain connected to the base of the transistor.

8. The computer of claim 7, wherein the routing circuit further comprises:
a second field-effect transistor having a gate controlled by an external control signal, a source connected to ground, and a drain connected to the base of the transistor.

9. The computer of claim 2, wherein the processor chipset comprises:
a processor; and
at least one controller hub communicably coupled to the processor, the audio codec, and the routing circuit.

10. A circuit for routing speaker beep signals in a computer having a processor chipset and internal and external chassis speakers, comprising:
first routing means for routing to the external chassis a speaker beep signal received from the processor chipset;
first volume control means for controlling a volume of the speaker beep signal routed to the external chassis speaker;
second routing means for routing to the internal chassis speaker the received speaker beep signal; and
second volume control means for adjusting a volume of the speaker beep signal routed to the internal chassis speaker in response to an external control signal.

11. The circuit of claim 10, wherein the first volume control means comprises:
audio coding/decoding means for mixing the received speaker beep signal with an audio signal received from the processor chipset, and for providing the external chassis speaker with a resulting combined speaker beep and audio signal.

12. The circuit of claim 11, wherein the audio coding/decoding means comprises means for adjusting a volume of the speaker beep signal routed to the external chassis speaker in response to an external control signal.

13. The circuit of claim 12, wherein the audio coding/decoding means comprises means for adjusting a volume of the audio signal in response to an external control signal.

14. A method for routing a speaker beep signal in a computer comprising:
routing the speaker beep signal to an external chassis speaker;
adjusting a magnitude of the speaker beep signal routed to the external chassis speaker in response to a control input; and
routing the speaker beep signal to an internal chassis speaker.

15. The method of claim 14, wherein adjusting a magnitude of the external speaker beep signal comprises:
routing the speaker beep signal to an audio codec; and
adjusting, by the audio codec, the magnitude of the speaker beep signal in response to an operator control input.

16. The method of claim 14, further comprising:
adjusting a magnitude of the speaker beep signal routed to the internal chassis speaker in response to a control input.

17. The method of claim 16, further comprising:
mixing the speaker beep signal routed to the external chassis speaker with an audio signal generated elsewhere in the computer prior to routing the speaker beep signal to an external chassis speaker.
